(19) United States
(12) Patent Application Publication
(10) Pub. No.: US 2025/0386645 A1
(43) Pub. Date: Dec. 18, 2025

(54) SEMICONDUCTOR ELEMENT

(71) Applicant: Lextar Electronics Corporation, Hsinchu City (TW)

(72) Inventors: Chun-Min LIN, Hsinchu City (TW); Jo-Hsiang CHEN, Hsinchu City (TW); Hsin-Lun SU, Hsinchu City (TW); Hsun CHANG, Hsinchu City (TW)

(21) Appl. No.: 19/242,496

(22) Filed: Jun. 18, 2025

(30) Foreign Application Priority Data
Jun. 18, 2024 (TW) 113122476

(51) Int. Cl. H10H 29/85; H10H 29/24; H10H 29/851; H10H 29/852

(52) U.S. Cl. CPC H10H 29/8508; H10H 29/24; H10H 29/851; H10H 29/852

(57) ABSTRACT

A semiconductor element is provided. The semiconductor element includes a substrate, a light-emitting diode chip, and an encapsulating layer. The substrate includes a bottom portion and an island-shaped protrusion, wherein the island-shaped protrusion is disposed on the bottom portion. The light-emitting diode chip is disposed on the island-shaped protrusion. The encapsulating layer is disposed on the light-emitting diode chip. The side surface of the island-shaped protrusion has a first roughness. The top surface of the island-shaped protrusion has a second roughness. The first roughness is different from the second roughness.

### CROSS REFERENCE TO RELATED APPLICATIONS

This application claims priority of Taiwan Patent Application No. TW 113122476, filed on Jun. 18, 2024, the content of the entirety of which is incorporated by reference herein.

### TECHNICAL FIELD

Some embodiments of the present disclosure relate to a semiconductor element, and, in particular, they relate to a semiconductor element including a light-emitting diode chip.

### BACKGROUND

Light-emitting diode (LED) chips have such characteristics as low power consumption, long life, and small size. However, semiconductor elements that include light-emitting diode chips may have poor optical properties and problems with reliability.

Therefore, although existing semiconductor elements have gradually met their intended uses, they still do not fully meet the requirements in all respects. Therefore, there are still some problems to be overcome regarding semiconductor elements.

### SUMMARY

In some embodiments, a semiconductor element is provided. The semiconductor element includes a substrate, a light-emitting diode chip, and an encapsulating layer. The substrate includes a bottom portion and an island-shaped protrusion. The island-shaped protrusion is disposed on the bottom portion. The light-emitting diode chip is disposed on the island-shaped protrusion. The encapsulating layer is disposed on the light-emitting diode chip. The side surface of the island-shaped protrusion has a first roughness. The top surface of the island-shaped protrusion has a second roughness. The first roughness is different from the second roughness.

The semiconductor element of the present disclosure may be applied in various types of electronic apparatus. In order to make the features and advantages of some embodiments of the present disclosure more understand, some embodiments of the present disclosure are listed below in conjunction with the accompanying drawings, and are described in detail as follows.

### BRIEF DESCRIPTION OF THE DRAWINGS

The present disclosure can be more fully understood from the following detailed description when read in conjunction with the accompanying drawings. It should be noted that, according to the standard practice in the industry, the various features are not drawn to scale. In fact, the dimensions of the various features may be arbitrarily increased or reduced for clarity.

FIG. 1 is a schematic cross-sectional view of a semiconductor element 1 according to some embodiments of the present disclosure.

FIG. 2 is a schematic cross-sectional view of a semiconductor element 1 according to some embodiments of the present disclosure.

FIG. 3 is a schematic top view of a semiconductor element 1 according to some embodiments of the present disclosure.

FIG. 4 is a schematic cross-sectional view of a semiconductor element 2 according to some embodiments of the present disclosure.

FIG. 5 is a schematic top view of a semiconductor element 2 according to some embodiments of the present disclosure.

FIG. 6 is a schematic cross-sectional view of a semiconductor element 3 according to some embodiments of the present disclosure.

FIG. 7 is a schematic top view of a semiconductor element 3 according to some embodiments of the present disclosure.

FIG. 8 is a schematic cross-sectional view of a semiconductor element 4 according to some embodiments of the present disclosure.

FIG. 9 is a schematic top view of a semiconductor element 4 according to some embodiments of the present disclosure.

### DETAILED DESCRIPTION

Semiconductor elements of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simple and clear description of some embodiments of the present disclosure, and does not imply any correlation between the different embodiments or structures discussed.

It should be understood that relative terms, such as “lower”, “bottom”, “higher”, or “top” may be used in various embodiments to describe the relative relationship of one element of the drawings to another element. It will be understood that if the device in the drawings is flipped to be upside down, elements described on the “lower” side would become elements on the “upper” side. The embodiments of the present disclosure can be understood together with the drawings, and the drawings of the present disclosure are also regarded as a portion of the disclosure.

Furthermore, when it is mentioned that a first element is located on or over a second element, it may include the embodiment which the first element and the second element are in direct contact and the embodiment which the first element and the second element are not in direct contact with each other, that is one or more layers of other materials is between the first element and the second element. However, if the first element is directly on the second element, it means that the first element and the second element are in direct contact.

In addition, it should be understood that ordinal numbers such as “first”, “second”, and the like used in the description and claims are used to identify elements and are not intended to imply and represent the element(s) have any previous ordinal numbers, and do not represent the order of a certain element and another element, or the order of the manufacturing method, and the use of these ordinal numbers is only used to clearly distinguished an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection can also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” can still be implied without the specific description of “approximately”, “about”, and “substantially”. The term “a range between a first value and a second value” or “a first value˜a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

Certain terms may be used throughout the specification and claims in the present disclosure to refer to specific elements. A person with ordinary skills in the art may refer to the same element by different terms. The present disclosure does not intend to distinguish between elements that have the same function but with different terms. In the following description and claims, terms such as “including”, “containing”, and “having” are open-ended words, so they should be interpreted as meaning “including but not limited to . . . ”. Therefore, when the terms “including”, “containing”, and/or “having” is used in the description of the present disclosure, it designates the presence of corresponding features, regions, steps, operations, and/or elements, but does not exclude the presence of one or more corresponding features, regions, steps, operations, and/or elements.

It should be understood that in the embodiments illustrated below, without departing from the spirit of the present disclosure, components in multiple different embodiments can be replaced, reorganized, and combined to complete other embodiments. Components in various embodiments can be used in any combination as long as they do not violate the spirit of the disclosure or conflict with each other.

Unless otherwise defined, all terms (including technical and scientific terms) used herein have the same meaning as commonly understood by a person of ordinary skills in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

Herein, the respective directions are not limited to three axes of the rectangular coordinate system, such as the X-axis, the Y-axis, and the Z-axis, and may be interpreted in a broader sense. For example, the X-axis, the Y-axis, and the Z-axis may be perpendicular to each other, or may represent different directions that are not perpendicular to each other, but the present disclosure is not limited thereto. For ease of description, hereinafter, the X-axis is a first direction D1 (in the width direction), the Y-axis is a second direction D2 (in the length direction), and the Z-axis is a third direction D3 (in the thickness/height direction). In some embodiments, the schematic cross-sectional views of the present disclosure are schematic cross-sectional views observing the XZ plane, and the schematic top views of the present disclosure are schematic top views observing the XY plane. In some embodiments, the third direction D3 may be a normal direction of the substrate.

In some embodiments, the terms “a distance between first element and second element” means that the distance is between the boundary of first element and the boundary of second element.

In some embodiments, the term “roughness” may be average roughness, maximum roughness, ten-point average roughness, or other roughness calculated by other suitable method.

In some embodiments, additional components may be added to the semiconductor element of the present disclosure. In some embodiments, some components of the semiconductor element of the present disclosure may be replaced or omitted. In some embodiments, additional operational steps may be provided before, during, and/or after the method of manufacturing the semiconductor element. In some embodiments, some of the operational steps may be replaced or omitted, and the order of some of the operational steps is interchangeable. Furthermore, it should be understood that some of the operational steps may be replaced or deleted for other embodiments of the method. Furthermore, in the present disclosure, the number and size of each component in the drawings are only for illustration and are not used to limit the scope of the present disclosure.

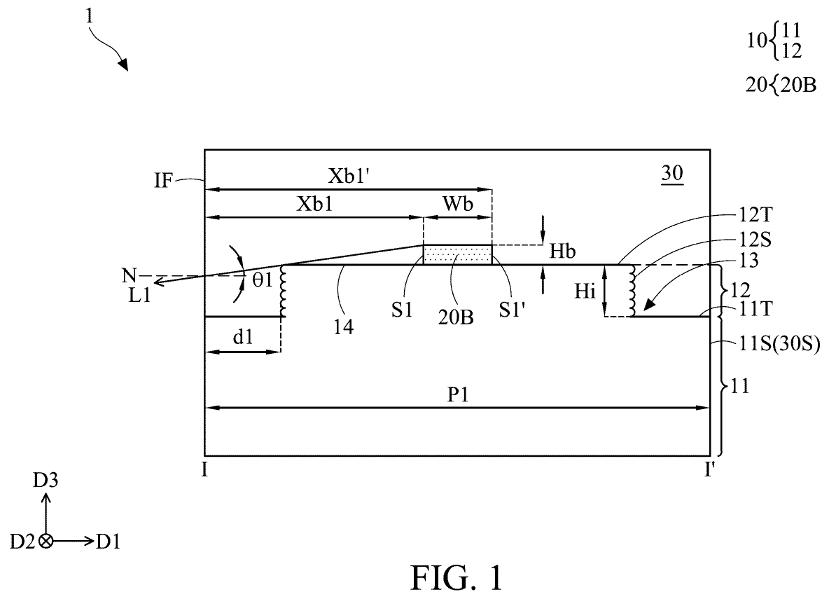

Referring to FIG. 1, it is a schematic cross-sectional view of a semiconductor element 1 according to some embodiments of the present disclosure. In some embodiments, a substrate 10 is provided. In some embodiments, the substrate 10 may include silicon, glass, sapphire, ceramic, polyimide (PI), polycarbonate (PC), polyethylene terephthalate (PET), polypropylene (PP), a printed circuit board (PCB), the like, or a combination thereof, but the present disclosure is not limited thereto.

In some embodiments, the substrate 10 may include a conductive structure (not shown), and the conductive structure may be electrically connected to a subsequently formed light-emitting diode chip. In some embodiments, the conductive structure may include metal, metal nitride, semiconductor material, other suitable conductive materials, or a combination thereof, but the present disclosure is not limited thereto. For example, the metal may include copper (Cu), gold (Au), silver (Ag), tin (Sn), nickel (Ni), indium (In), platinum (Pt), titanium (Ti), chromium (Cr), tungsten (W), aluminum (Al), molybdenum (Mo), magnesium (Mg), zinc (Zn), alloys thereof, or a combination thereof. In some embodiments, the conductive structure may include a transparent conductive oxide (TCO). For example, the transparent conductive oxide may include indium tin oxide (ITO), aluminum zinc oxide (AZO), tin oxide (SnO), zinc oxide (ZnO), indium zinc oxide (IZO), indium gallium zinc oxide (IGZO), indium tin zinc oxide (ITZO), antimony tin oxide (ATO), other suitable transparent conductive oxides, or a combination thereof.

In some embodiments, the substrate 10 includes a bottom portion 11 and an island-shaped protrusion 12, and the island-shaped protrusion 12 may be disposed on the bottom portion 11. In some embodiments, the island-shaped protrusion 12 and the bottom portion 11 may have the same material. In other words, there may be substantially no interface between the island-shaped protrusion 12 and the bottom portion 11. In some embodiments, the island-shaped protrusion 12 may be integrally formed with the bottom portion 11. In some embodiments, the island-shaped protrusion 12 may be formed by a processing process such as a cutting process. For example, a substrate material may be provided. Next, a first cutting process may be performed to remove a portion of the substrate material, thereby forming a substrate 10 having an island-shaped protrusion 12 on a bottom portion 11. In some embodiments, after performing the first cutting process, a recess 13 may be formed on a top surface 11T of the bottom portion 11, and the recess 13 may surround the island-shaped protrusion 12. In some embodiments, the first cutting process may include laser cutting, blade cutting, other suitable processes, or a combination thereof, but the present disclosure is not limited thereto. For example, the first cutting process may use a blade cutting process.

In some embodiments, after performing the blade cutting process, a roughness of a side surface 12S of the island-shaped protrusion 12 in contact with a side surface of the blade may correspond to a roughness of the blade. In some embodiments, the side surface 12S of the island-shaped protrusion 12 has a first roughness Ra1, the top surface 12T of the island-shaped protrusion 12 has a second roughness Ra2, and the first roughness Ra1 is different from the second roughness Ra2. In some embodiments, the first roughness Ra1 of the side surface 12S of the island-shaped protrusion 12 cut by the blade may be greater than the second roughness Ra2 of the top surface 12T of the island-shaped protrusion 12 not cut by the blade.

In some embodiments, the first roughness Ra1 of the side surface 12S of the island-shaped protrusion 12 may be greater than or equal to 0.28 um. For example, the first roughness Ra1 may be 0.28 um, 0.281 um, 0.29 um, 0.30 um, 0.303 um, 0.31 um, 0.32 um, 0.35 um, or any value or any range of values between the aforementioned values, but the present disclosure is not limited thereto. In some embodiments, the second roughness Ra2 of the top surface 12T of the island-shaped protrusion 12 may be less than or equal to 0.25 um. For example, the second roughness Ra2 may be 0.25 um, 0.245 um, 0.243 um, 0.24 um, 0.23 um, 0.22 um, 0.2 um, or any value or any range of values between the aforementioned values, but the present disclosure is not limited thereto. Accordingly, when the first roughness Ra1 of the side surface 12S of the island-shaped protrusion 12 is greater than the second roughness Ra2 of the top surface 12T of the island-shaped protrusion 12, the contact area between the island-shaped protrusion 12 and the subsequently formed encapsulating layer 30 may be increased. Therefore, the bonding strength between the island-shaped protrusion 12 and the subsequently formed encapsulating layer 30 may be improved. In addition, when the first roughness Ra1 is greater than the second roughness Ra2, it means that the first cutting process may be a blade cutting process.

In some embodiments, the light-emitting diode chip 20 may be disposed on the island-shaped protrusion 12. In some embodiments, the light-emitting diode chip 20 may include a mini light-emitting diode (mini LED) chip, a micro light-emitting diode (micro LED) chip, the like, or a combination thereof, but the present disclosure is not limited thereto. In some embodiments, in the first direction D1, the light-emitting diode chip 20 may have a chip width Wb. In some embodiments, the chip width Wb of the light-emitting diode chip 20 may be less than or equal to 200 um. For example, the chip width Wb may be 200 um, 175 um, 150 um, 125 um, 100 um, or any value or any range of values between the aforementioned values, but the present disclosure is not limited thereto. Since the light-emitting diode chip 20 may be a small-sized chip, the semiconductor element may also be a small-sized element. The substrate 10 and the subsequently formed encapsulating layer 30 may have an insufficient contact area when there is no island-shape protrusion 12, and the bonding strength between the encapsulating layer 30 and the substrate 10 will be reduced. Thus, moisture, oxygen, or other impurities are easily infiltrated from the interface between the encapsulating layer 30 and the substrate 10, thereby causing the semiconductor element to fail. However, since the present disclosure includes the island-shaped protrusion 12, the bonding strength of the encapsulating layer 30 may be improved by the island-shaped protrusion 12, thereby achieving the effect of preventing the semiconductor element from failing.

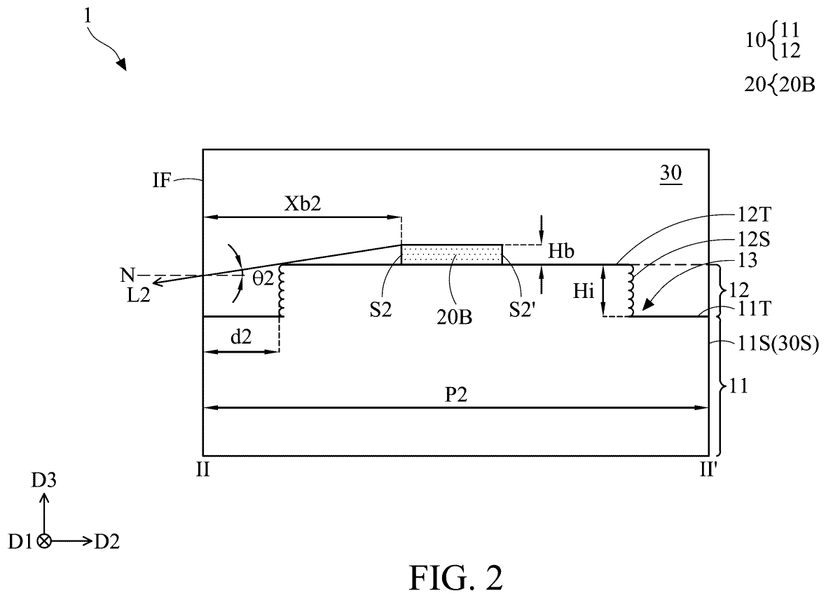

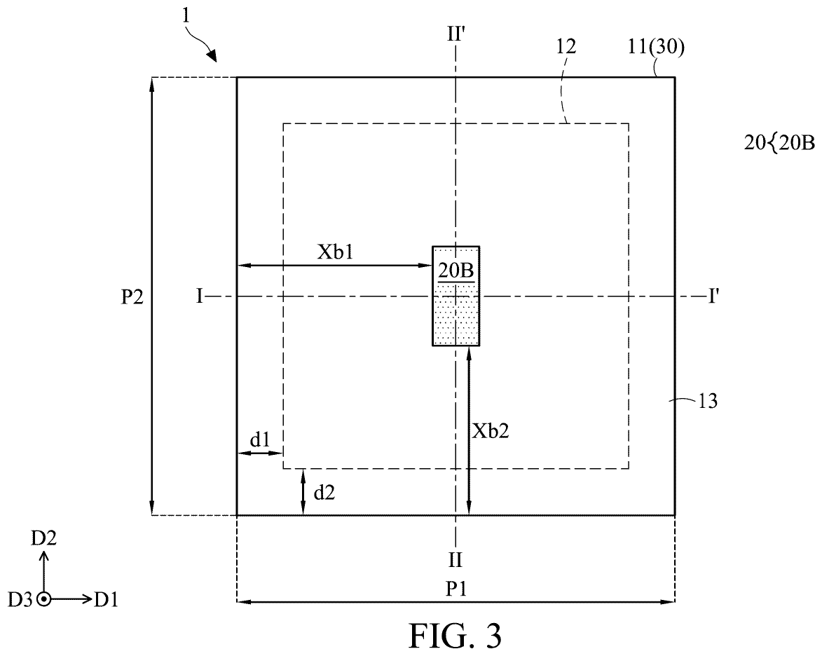

In some embodiments, as shown in FIG. 1 and the subsequent FIGS. 2 and 3, the light-emitting diode chip 20 may include one blue light-emitting diode chip 20B, but the present disclosure is not limited thereto. In some embodiments, the light-emitting diode chip 20 may comprises one or more light-emitting diode chips according to the requirements of optical properties. In some embodiments, the light-emitting diode chip 20 may emit a red light, a green light, a blue light, an ultraviolet light (UV light), or other light with suitable wavelengths. In some embodiments, the light-emitting diode chip 20 may include at least one blue light-emitting diode chip 20B. In some embodiments, the light-emitting diode chip 20 may further include a green light-emitting diode chip 20G or a red light-emitting diode chip 20R.

In some embodiments, the encapsulating layer 30 may be disposed on the light-emitting diode chip 20. In some embodiments, the encapsulating layer 30 may cover the bottom portion 11 and the island-shaped protrusion 12 of the substrate 10 and the light-emitting diode chip 20. In some embodiments, the encapsulating layer 30 may be in direct contact with the bottom surface and the side surfaces of the recess 13. In some embodiments, the encapsulating layer 30 may completely fill or partially fill the recess 13. In some embodiments, the encapsulating layer 30 may be in direct contact with the side surface 12S of the island-shaped protrusion 12 with greater roughness, so as to enhance the bonding strength of the encapsulating layer 30.

In some embodiments, a plurality of semiconductor elements 1 can be formed at the same time. After forming the encapsulating layer 30, a semi-finished structure of the plurality of semiconductor elements 1 are formed in a connecting status, and a second cutting process may be performed to singulate the plurality of semiconductor elements 1. That is, the plurality of semiconductor elements 1 are separated from each other after the second cutting process. In some embodiments, the second cutting process may be the same as or different from the first cutting process. For example, the second cutting process may use a blade cutting process. In some embodiments, a blade width of the second cutting process may be smaller than a blade width of the first cutting process. In some embodiments, after performing the second cutting process, the side surface 11S of the bottom portion 11 of the substrate 10 may be aligned with the side surface 30S of the encapsulating layer 30.

In some embodiments, the encapsulating layer 30 may include a light-transmitting matrix, and the light emitted by the light-emitting diode chip 20 may penetrate the light-transmitting matrix of the encapsulating layer 30. In some embodiments, the light-transmitting matrix may include epoxy, silicone, the like, or a combination thereof.

In some embodiments, the encapsulating layer 30 may include a wavelength conversion material, and the wavelength conversion material may be dispersed in the light-transmitting matrix. In some embodiments, the wavelength conversion material may include a red color conversion material, a blue color conversion material, a green color conversion material, a yellow color conversion material, other suitable color conversion materials, or a combination thereof. In some embodiments, the color conversion material may be quantum dots or phosphors, but the present disclosure is not limited thereto.

In some embodiments, as shown in FIG. 1, in the first direction D1, the blue light-emitting diode chip 20B may emit a first light L1, and the first light L1 is a blue light. The first light L1 may pass through the encapsulating layer 30 to the surrounding environment. In some embodiments, the encapsulating layer 30 may have a first refractive index n1, the surrounding environment may have a second refractive index n2, and the first refractive index n1 of the encapsulating layer 30 may be greater than the second refractive index n2 of the surrounding environment. When the first light L1 enters a medium with a lower refractive index from a medium with a higher refractive index, the total internal reflection may occur. That is, the first light L1 may not enter the surrounding environment but is totally reflected to remain in the semiconductor element 1. If the first light L1 is totally reflected, the totally reflected first light L1 may irradiate the surface of the substrate 10 again. Since the first light L1 is a blue light with short-wavelength and high-energy, the substrate 10 may be degraded (for example, deteriorated and whitened) due to the repeated irradiation of the first light L1, resulting in reduced bonding strength at the interface 14 between the substrate 10 and the encapsulating layer 30, thereby affecting the reliability of the semiconductor element 1. Therefore, in order to improve the reliability, the semiconductor element 1 of the present disclosure may reduce the total internal reflection of the first light L1 and reduce the extent to which the substrate 10 is irradiated by the first light L1 (for example, irradiation range and/or irradiation time). The detailed instructions are as follows.

In some embodiments, as shown in FIG. 1, the interface between the encapsulating layer 30 and the surrounding environment is referred to as a refractive interface IF, and the angle between the first light L1 and the normal line N of the refractive interface IF (that is, the incident angle of the first light L1 on the refractive interface IF) is defined as a first angle θ1. When: n1×sin(θ1)≥n2×sin(90° is satisfied, that is,

$$θ1 \geq {sin}^{- 1} ( \frac{n 2}{n 1} ) ,$$

the total internal reflection occurs. On the contrary, if

$$θ1 < {sin}^{- 1} ( \frac{n 2}{n 1} ) ,$$

the total internal reflection will not occur.

In some embodiments, the first refractive index n1 of the encapsulating layer 30 may be greater than 1. For example, the first refractive index n1 may be 1.1, 1.2, 1.3, 1.4, 1.5, 1.54, 1.6, 1.7, or any value or any range of values between the aforementioned values, but the present disclosure is not limited thereto. In some embodiments, the surrounding environment may be air, vacuum, semi-vacuum, or other suitable environments, so as to change the second refractive index n2 of the surrounding environment. For example, when the surrounding environment is air and the second refractive index n2 of the surrounding environment is 1, the first light L1 is not total reflected when

$$θ1 < {sin}^{- 1} ( \frac{1}{n 1} )$$

(Formula (a1)) is satisfied.

In some embodiments, in the first direction D1, there may be a first pitch d1 between the side surface 12S of the island-shaped protrusion 12 and the side surface 11S of the bottom portion 11. In some embodiments, in the first direction D1, the blue light-emitting diode chip 20B may have opposite first side surfaces S1 and S1′. In some embodiments, in the first direction D1, there may be a first distance Xb1 between the (left) first side surface S1 of the blue light-emitting diode chip 20B and the (left) side surface 11S of the bottom portion 11. In other words, there is a first distance Xb1 between the first side surface S1 of the blue light-emitting diode chip 20B and the nearest side surface 11S of the bottom portion 11.

In some embodiments, in the third direction D3, the blue light-emitting diode chip 20B has a chip height Hb. In some embodiments, the chip height Hb may be greater than or equal to 5 um and less than or equal to 11 um. For example, the chip height Hb may be 5 um, 6 um, 7 um, 8 um, 9 um, 10 um, 11 um, or any value or any range of values between the aforementioned values, but the present disclosure is not limited thereto.

Therefore, according to the definition of tangent (tan), the first angle θ1 and the first pitch d1 may satisfy

$$θ1 = {tan}^{- 1} \frac{Hb}{( Xb 1 - d 1 )}$$

(Formula (a2)).

Furthermore, if it is desired to avoid total internal reflection of the first light L1, Formula (a1) is substituted into Formula (a2). Therefore,

$${tan}^{- 1} \frac{Hb}{( Xb 1 - d 1 )} < {sin}^{- 1} ( \frac{1}{n 1} )$$

may be obtained. After derivation, it may be organized as

$$d 1 < Xb 1 - \frac{Hb}{\sqrt{1 - {( \frac{1}{n 1} )}^{2}}} . \qquad ( Formula ( a3 ) )$$

Since the semiconductor element 1 of the present embodiment has the island-shaped protrusion 12, the first pitch d1 may be greater than 0. Therefore, it can satisfy

$$0 < d 1 < Xb 1 - \frac{Hb}{\sqrt{1 - {( \frac{1}{n 1} )}^{2}}}$$

(Formula (A)). Accordingly, when the semiconductor element 1 of the present disclosure satisfies formula (A), the first light L1 emitted by the blue light-emitting diode chip 20B will not be totally reflected, and the island-shaped protrusion 12 may reduce the range of the surface of the substrate 10 where the first light L1 directly irradiates. For example, a part of the first light L1 will be blocked by the island-shaped protrusion 12 and will not directly irradiate the top surface 11T of the bottom portion 11, thereby reducing the probability of degradation of the substrate 10, thereby improving the reliability and optical properties of the semiconductor element 1.

In other embodiments, the chip width Wb of the light-emitting diode chip 20 may be further considered, that is, the situation where the first light L1 from the right side (the first side surface S1′) of the light-emitting diode chip 20 irradiates the top surface 11T of the bottom portion 11 (on the left side) may be further considered. In some embodiments, in the first direction D1, there may be a first distance Xb1′ between the first side surface S1′ of the blue light-emitting diode chip 20B and the side surface 11S of the bottom portion 11 (on the left side), and Xb1′=Xb1+Wb (Formula (a4)) is satisfied.

Substituting Formula (a4) into Formula (a3),

$$0 < d 1 < Xb {1}^{′} - Wb - \frac{Hb}{\sqrt{1 - {( \frac{1}{n 1} )}^{2}}}$$

(Formula (A)) may be obtained. Therefore, when the chip height Hb and the first refractive index n1 are constant, the chip width Wb is larger, the first pitch d1 is smaller.

In some embodiments, as shown in FIG. 1, the first pitch d1 may be greater than or equal to 10 um and less than or equal to 20 um. For example, the first pitch d1 may be 10 um, 11 um, 12 um, 13 um, 14 um, 15 um, 16 um, 17 um, 18 um, 19 um, 20 um, or any value or any range of values between the aforementioned values, but the present disclosure is not limited thereto.

In some embodiments, as shown in FIG. 1, in the third direction D3, the island-shaped protrusion 12 may have a protrusion height Hi. In order to prevent the first light L1 from directly irradiating the top surface 11T of the bottom portion 11, the semiconductor element 1 must meet

$$\frac{Hi}{d 1} \geq \frac{Hb}{( Xb 1 - d 1 )} .$$

Thus, it may be organized as

$$\frac{Hi \times Xb 1}{Hb + Hi} \geq d 1$$

(Formula (B)), or organized as

$$Hi \geq \frac{Hb \times d 1}{( Xb 1 - d 1 )}$$

(Formula (C)). Therefore, since the semiconductor element 1 of the present disclosure satisfies Formula (B) and Formula (C), the probability of the substrate 10 being degraded by the first light L1 emitted by the blue light-emitting diode chip 20B is reduced, thereby improving the reliability and optical properties of the semiconductor element 1.

In some embodiments, the protrusion height Hi may be greater than or equal to 35 um and less than or equal to 45 um. For example, the protrusion height Hi may be 35 um, 36 um, 37 um, 38 um, 39 um, 40 um, 41 um, 42 um, 43 um, 44 um, 45 um, or any value or any range of values between the aforementioned values, but the present disclosure is not limited thereto.

In the following, the same or similar reference numerals and descriptions are omitted.

Referring to FIG. 2, it is a schematic cross-sectional view of a semiconductor element 1 according to some embodiments of the present disclosure. In some embodiments, as shown in FIG. 2, in the second direction D2, the blue light-emitting diode chip 20B may emit a second light L2. The second light L2 may pass through the encapsulating layer 30 to the surrounding environment. The angle between the second light L2 and the normal line N of the refractive interface IF (that is, the incident angle of the second light L2 on the refractive interface IF) is defined as a second angle θ2. In some embodiments, in the second direction D2, there may be a second pitch d2 between the side surface 12S of the island-shaped protrusion 12 and the side surface 11S of the bottom portion 11. In some embodiments, in the second direction D2, the blue light-emitting diode chip 20B may have opposite second side surfaces S2, S2′. In some embodiments, in the second direction D2, there may be a second distance Xb2 between the second side surface S2 of the blue light-emitting diode chip 20B and the nearest side surface 11S of the bottom portion 11.

In some embodiments, as shown in FIG. 2, the second pitch d2 may be greater than or equal to 10 um and less than or equal to 20 um. For example, the second pitch d2 may be 10 um, 11 um, 12 um, 13 um, 14 um, 15 um, 16 um, 17 um, 18 um, 19 um, 20 um, or any value or any range of values between the aforementioned values, but the present disclosure is not limited thereto. In some embodiments, the first pitch d1 and the second pitch d2 may be the same or different according to the requirements of optical properties.

Similar to the above, in some embodiments, as shown in FIG. 2, in order to avoid total internal reflection of the second light L2,

$$0 < d 2 < Xb 2 - \frac{Hb}{\sqrt{1 - {( \frac{1}{n 1} )}^{2}}}$$

(Formula (D)) is satisfy. Furthermore, in order to prevent the second light L2 from directly irradiating the top surface 11T of the bottom portion 11, it is possible to satisfy

$$\frac{Hi \times Xb 2}{Hb + Hi} \geq d 2$$

### (Formula (E)) and

$$Hi \geq \frac{Hb \times d 2}{( Xb 2 - d 2 )}$$

### (Formula (F)).

Referring to FIG. 3, it is a schematic top view of a semiconductor element 1 according to some embodiments of the present disclosure. FIG. 1 shows a schematic cross-sectional view taken along line I-I′ in FIG. 3, and FIG. 2 shows a schematic cross-sectional view taken along line II-II′ in FIG. 3.

As shown in FIG. 3, in some embodiments, in the first direction D1, the semiconductor element 1 may have an element width P1. In some embodiments, the element width P1 may be greater than or equal to 200 um and less than or equal to 300 um. For example, the element width P1 may be 200 um, 210 um, 220 um, 230 um, 240 um, 250 um, 260 um, 270 um, 280 um, 290 um, 300 um, or any value or any range of values between the aforementioned values, but the present disclosure is not limited thereto.

In some embodiments, in the second direction D2, the semiconductor element 1 may have an element length P2. In some embodiments, the element length P2 may be greater than or equal to 200 um and less than or equal to 300 um. For example, the element length P2 may be 200 um, 210 um, 220 um, 230 um, 240 um, 250 um, 260 um, 270 um, 280 um, 290 um, 300 um, or any value or any range of values between the aforementioned values, but the present disclosure is not limited thereto. In some embodiments, the element width P1 and the element length P2 may be the same or different depending on the requirements of optical properties.

In some embodiments, since the semiconductor element 1 of the present disclosure has the island-shaped protrusion 12, the first pitch d1 and the second pitch d2 may be greater than 0. A projection area of the island-shaped protrusion 12 on the bottom portion 11 is calculated based on the above-mentioned (Formula (B)) and (Formula (E)). In some embodiments, when viewed from a top view, the total area of the bottom portion 11 is the product of the element width P1 and the element length P2 (P1×P2). In some embodiments, the projection area of the island-shaped protrusion 12 on the bottom portion 11 is

$$( P 1 - \frac{2 \times Hi \times Xb 1}{Hb + Hi} ) \times ( P 2 - \frac{2 \times Hi \times Xb 2}{Hb + Hi} )$$

(Formula (g1)). Therefore, the projection area of the island-shaped protrusion 12 on the bottom portion 11 accounts for A % of the total area of the bottom portion 11, and satisfies

$$\frac{( P 1 - \frac{2 \times Hi \times Xb 1}{Hb + Hi} ) \times ( P 2 - \frac{2 \times Hi \times Xb 2}{Hb + Hi} )}{P 1 \times P 2} \times 100 \% \leq A \% < 100 \%$$

### (Formula (G)).

In some embodiments, A % may be in a range from 85% to 93%. For example, A % may be 85%, 86%, 87%, 87.35%, 88%, 89%, 90%, 90.25%, 91%, 92%, 93%, or any value or any range of values between the aforementioned values, but the present disclosure is not limited thereto. When A % is greater than 93%, the first light L1 and/or the second light L2 emitted by the blue light-emitting diode chip 20B may still irradiate the top surface 11T of the bottom portion 11. When A % is less than 85%, the process flexibility of disposing the blue light-emitting diode chip 20B on the island-shaped protrusion 12 may be reduced.

In some embodiments, the island-shaped protrusion 12 of the semiconductor element 1 disclosed herein increases the contact area between the encapsulating layer 30 and the substrate 10, thereby improving the bonding strength between the encapsulating layer 30 and the substrate 10. Compared with the embodiment without the island-shaped protrusion 12, the semiconductor element 1 with the island-shaped protrusion 12 may withstand a larger thrust in the thrust test. In some embodiments, compared with the embodiments without the island-shaped protrusion 12, the semiconductor element 1 of the present disclosure may reduce the failure quantity of the light-emitting diode chips at a temperature of 85° C. and a humidity of 85%. Therefore, the semiconductor element 1 of the present disclosure can have excellent reliability and optical properties.

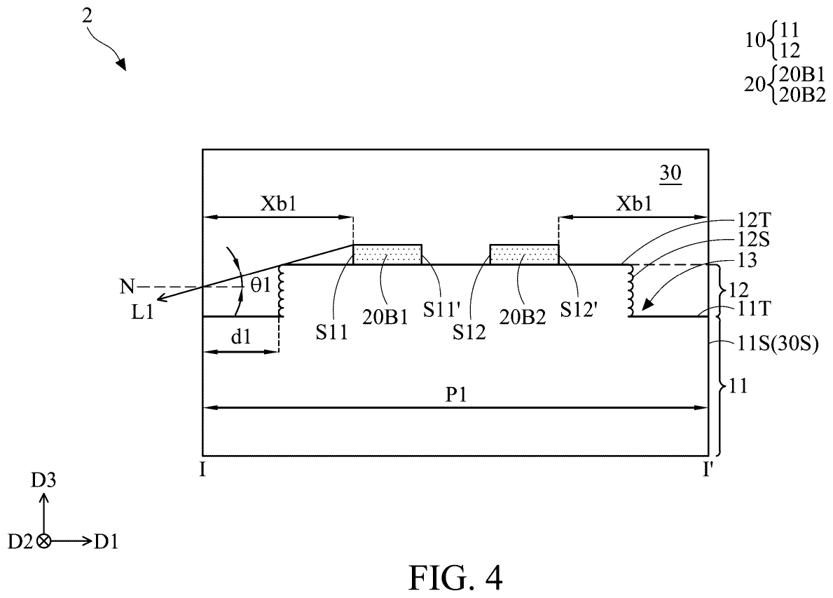

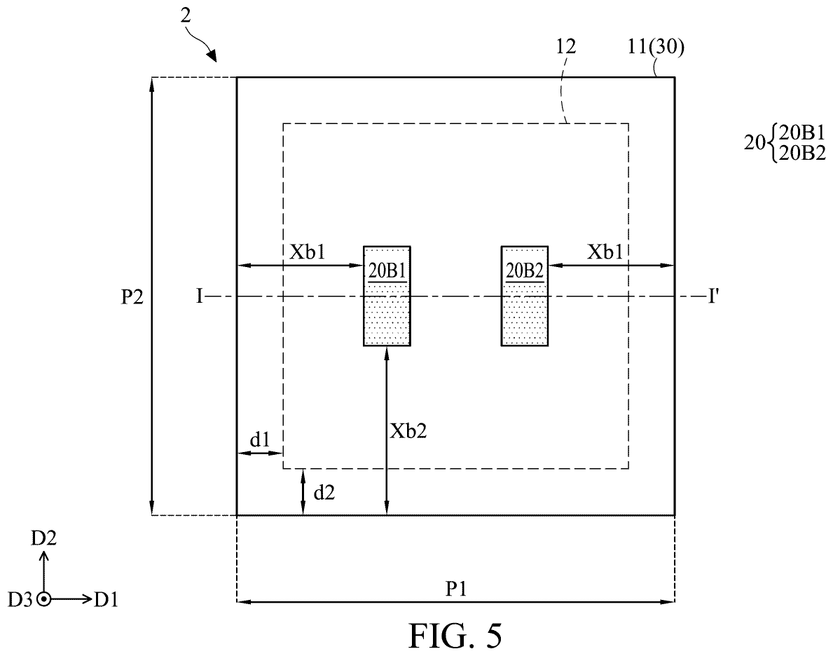

Referring to FIGS. 4 and 5, which are a schematic cross-sectional view and a schematic top view of the semiconductor element 2 according to some embodiments of the present disclosure. FIG. 4 shows a schematic cross-sectional view taken along line I-I′ in FIG. 5. In some embodiments, FIG. 4 and FIG. 5 show that the light-emitting diode chip 20 may include two blue light-emitting diode chips 20B1 and 20B2, but the present disclosure is not limited thereto. In some embodiments, the semiconductor element 2 may satisfy the aforementioned Formula (A) to Formula (G).

In some embodiments, in the first direction D1, the blue light-emitting diode chip 20B1 may have opposite first side surfaces S11, S11′, and the blue light-emitting diode chip 20B2 may have opposite first side surfaces S12, S12′. In some embodiments, in the first direction D1, there may be a first distance Xb1 between the first side surface S11 of the blue light-emitting diode chip 20B1 and the nearest side surface 11S of the bottom portion 11. In some embodiments, in the first direction D1, there may be a first distance Xb1 between the first side surface S12′ of the blue light-emitting diode chip 20B2 and the nearest side surface 11S of the bottom portion 11. In some embodiments, when the element width P1 of the semiconductor element 2 is the same as the element width P1 of the semiconductor element 1, the first distance Xb1 of the semiconductor element 2 may be smaller than the first distance Xb1 of the semiconductor element 1, and the first pitch d1 of the semiconductor element 2 may be smaller than the first pitch d1 of the semiconductor element 1.

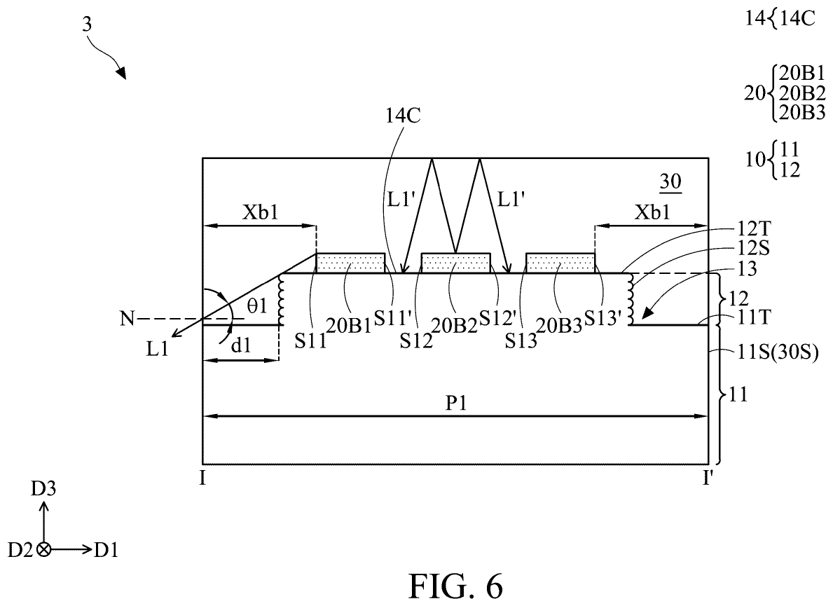

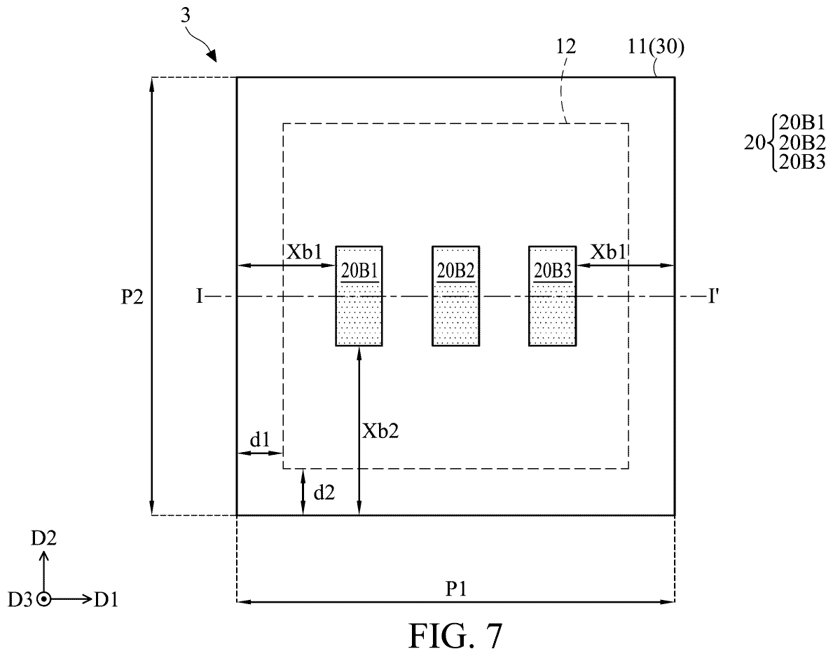

Referring to FIGS. 6 and 7, which are a schematic cross-sectional view and a schematic top view of the semiconductor element 3 according to some embodiments of the present disclosure. FIG. 6 shows a schematic cross-sectional view taken along line I-I′ in FIG. 7. In some embodiments, FIG. 6 and FIG. 7 show that the light-emitting diode chip 20 may include three blue light-emitting diode chips 20B1, 20B2, and 20B3, but the present disclosure is not limited thereto. In some embodiments, the semiconductor element 3 may satisfy the aforementioned Formula (A) to Formula (G).

In some embodiments, in the first direction D1, the blue light-emitting diode chip 20B3 may have opposite first side surfaces S13, S13′. In some embodiments, in the first direction D1, there may be a first distance Xb1 between the first side surface S11 of the blue light-emitting diode chip 20B1 and the nearest side surface 11S of the bottom portion 11. In some embodiments, in the first direction D1, there may be a first distance Xb1 between the first side surface S13′ of the blue light-emitting diode chip 20B3 and the nearest side surface 11S of the bottom portion 11. In some embodiments, when the element width P1 of the semiconductor element 3 is the same as the element width P1 of the semiconductor element 1, the first distance Xb1 of the semiconductor element 3 may be smaller than the first distance Xb1 of the semiconductor element 1, and the first pitch d1 of the semiconductor element 3 may be smaller than the first pitch d1 of the semiconductor element 1.

In some embodiments, when the light-emitting diode chip 20 includes three blue light-emitting diode chips 20B1, 20B2, and 20B3 arranged in sequence in the first direction D1. The first pitch d1 between the side surface 12S of the island-shaped protrusion 12 and the side surface 11S of the bottom portion 11 can be estimate by considering the distances between the blue light-emitting diode chip 20B1 and 20B3 and the side surface 11S of the bottom portion 11. Since the blue light-emitting diode chip 20B2 is disposed between the blue light-emitting diode chips 20B1 and 20B3, the light emitted by the blue light-emitting diode chip 20B2 (for example, the first light L1′) substantially irradiates a central portion 14C of the interface 14 between the encapsulating layer 30 and the substrate 10. In other words, the light emitted by the blue light-emitting diode chip 20B2 is substantially away from the side surface 11S of the bottom portion 11, that is, away from the edge of the substrate 10. Therefore, the light emitted by the blue light-emitting diode chip 20B2 is not easy to directly irradiate the top surface 11T of the bottom portion 11. Accordingly, when the blue light-emitting diode chips 20B1 and 20B3 satisfy the above-mentioned Formula (A) to Formula (G), the reliability and optical characteristics of the semiconductor element 3 may be improved.

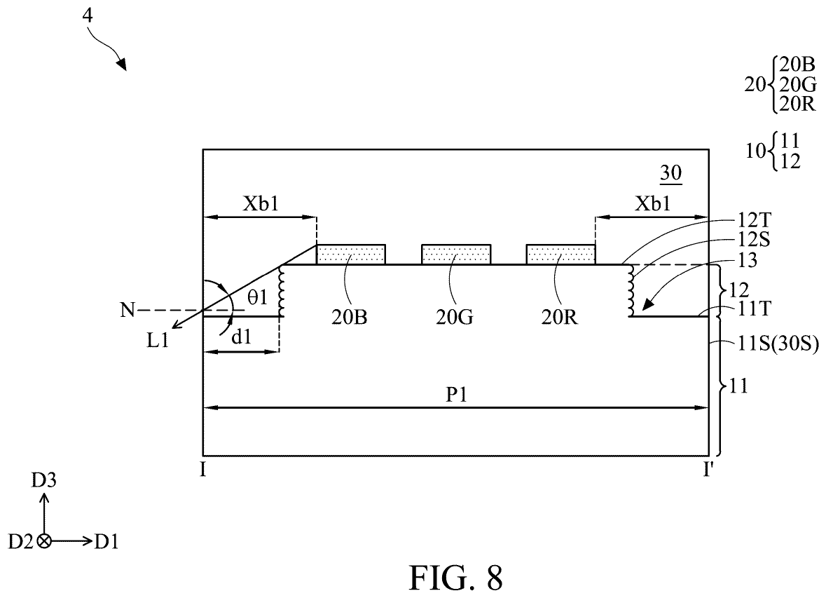

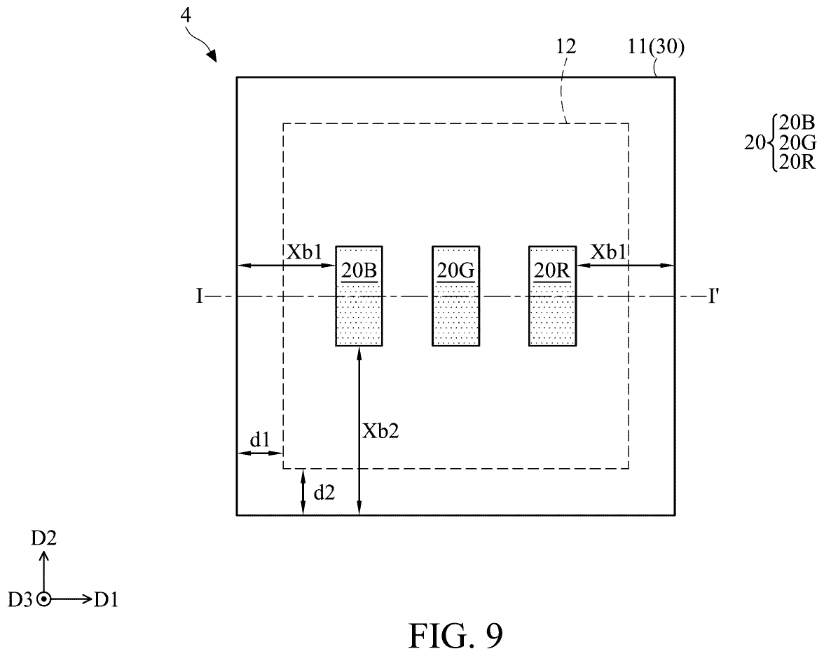

Referring to FIGS. 8 and 9, which are a schematic cross-sectional view and a schematic top view of the semiconductor element 4 according to some embodiments of the present disclosure. FIG. 8 shows a schematic cross-sectional view taken along line I-I′ in FIG. 9. In some embodiments, FIG. 8 and FIG. 9 show that the light-emitting diode chip 20 may include a blue light-emitting diode chip 20B, a green light-emitting diode chip 20G, and a red light-emitting diode chip 20R arranged in sequence in the first direction D1, but the present disclosure is not limited thereto. In some embodiments, the semiconductor element 4 may satisfy the aforementioned Formula (A) to Formula (G). Since the blue light-emitting diode chip 20B is disposed adjacent to the side surface 11S of the bottom portion 11, when the blue light-emitting diode chip 20B satisfies the above-mentioned Formula (A) to Formula (G), the reliability and optical characteristics of the semiconductor element 4 may be improved.

In summary, the present disclosure may increase the contact area between the substrate and the encapsulating layer by adjusting the roughness of the top surface and the side surface of the island-shaped protrusion. Therefore, the bonding strength between the substrate and the encapsulating layer may be improved. Furthermore, by respectively adjusting the size parameters of the components in the semiconductor element, the present disclosure may prevent the high-energy light emitted by the light-emitting diode chip from degrading the substrate and causing a decrease in the bonding strength between the encapsulating layer and the substrate. Thus, moisture, oxygen, or other impurities may be prevented from penetrating through the interface between the encapsulating layer and the substrate and causing the light-emitting diode chip to fail. Therefore, the reliability and optical characteristics of the semiconductor element including the light-emitting diode chip disclosed in the present disclosure may be improved.

The features among the various embodiments may be arbitrarily combined as long as they do not violate or conflict with the spirit of the disclosure. In addition, the scope of the present disclosure is not limited to the process, machine, manufacturing, material composition, device, method, and step in the specific embodiments described in the specification. A person of ordinary skill in the art will understand current and future processes, machine, manufacturing, material composition, device, method, and step from the content disclosed in some embodiments of the present disclosure, as long as the current or future processes, machine, manufacturing, material composition, device, method, and step performs substantially the same functions or obtain substantially the same results as the present disclosure. Therefore, the scope of the present disclosure includes the abovementioned process, machine, manufacturing, material composition, device, method, and steps. It is not necessary for any embodiment or claim of the present disclosure to achieve all of the objects, advantages, and/or features disclosed herein.

The foregoing outlines features of several embodiments of the present disclosure, so that a person of ordinary skill in the art may better understand the aspects of the present disclosure. A person of ordinary skill in the art should appreciate that the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor element, comprising:
a substrate, comprising a bottom portion and an island-shaped protrusion,
wherein the island-shaped protrusion is disposed on the bottom portion;
a light-emitting diode chip disposed on the island-shaped protrusion; and
an encapsulating layer disposed on the light-emitting diode chip;
wherein a side surface of the island-shaped protrusion has a first roughness, a top surface of the island-shaped protrusion has a second roughness, and the first roughness is different from the second roughness.

2. The semiconductor element as claimed in claim 1, wherein the first roughness of the side surface of the island-shaped protrusion is greater than the second roughness of the top surface of the island-shaped protrusion.

3. The semiconductor element as claimed in claim 1, wherein the first roughness of the side surface of the island-shaped protrusion is greater than or equal to 0.28 um.

4. The semiconductor element as claimed in claim 1, wherein the second roughness of the top surface of the island-shaped protrusion is less than or equal to 0.25 um.

5. The semiconductor element as claimed in claim 1, wherein the encapsulating layer covers the bottom portion, the island-shaped protrusion, and the light-emitting diode chip.

6. The semiconductor element as claimed in claim 1, wherein a side surface of the bottom portion is aligned with a side surface of the encapsulating layer.

7. The semiconductor element as claimed in claim 1, wherein a first pitch between the side surface of the island-shaped protrusion and a side surface of the bottom portion is d1, and satisfies:
$$0 < d 1 < Xb 1 - \frac{Hb}{\sqrt{1 - {( \frac{1}{n 1} )}^{2}}}$$
wherein,
Xb1 is a first distance between a first side surface of the light-emitting diode chip and the side surface of the bottom portion;
Hb is a chip height of the light-emitting diode chip; and
n1 is a refractive index of the encapsulating layer.

8. The semiconductor element as claimed in claim 7, wherein the first pitch is greater than or equal to 10 um and less than or equal to 20 um.

9. The semiconductor element as claimed in claim 7, wherein the refractive index of the encapsulating layer is greater than 1.

10. The semiconductor element as claimed in claim 1, wherein a first pitch between the side surface of the island-shaped protrusion and a side surface of the bottom portion is d1, and satisfies:
$$\frac{Hi \times Xb 1}{Hb + Hi} \geq d 1$$
wherein,
Xb1 is a first distance between a first side surface of the light-emitting diode chip and the side surface of the bottom portion;
Hb is a chip height of the light-emitting diode chip; and
Hi is a protrusion height of the island-shaped protrusion.

11. The semiconductor element as claimed in claim 1, wherein a protrusion height of the island-shaped protrusion is Hi, and satisfies:
$$Hi \geq \frac{Hb \times d 1}{( Xb 1 - d 1 )}$$
wherein,
Hb is a chip height of the light-emitting diode chip;
d1 is a first pitch between the side surface of the island-shaped protrusion and a side surface of the bottom portion; and
Xb1 is a first distance between a first side surface of the light-emitting diode chip and the side surface of the bottom portion.

12. The semiconductor element as claimed in claim 10, wherein the protrusion height is greater than or equal to 35 um and less than or equal to 45 um.

13. The semiconductor element as claimed in claim 1, wherein a projection area of the island-shaped protrusion on the bottom portion accounts for A % of a total area of the bottom portion, and satisfies:
$$\frac{( P 1 - \frac{2 \times Hi \times Xb 1}{Hb + Hi} ) \times ( P 2 - \frac{2 \times Hi \times Xb 2}{Hb + Hi} )}{P 1 \times P 2} \times 100 \% \leq A \% < 100 \%$$
wherein,
P1 is a width of the semiconductor element;
P2 is a length of the semiconductor element;
Hi is a protrusion height of the island-shaped protrusion;
Hb is a chip height of the light-emitting diode chip;
Xb1 is a first distance between a first side surface of the light-emitting diode chip and the side surface of the bottom portion; and
Xb2 is a second distance between a second side surface of the light-emitting diode chip and the side surface of the bottom portion.

14. The semiconductor element as claimed in claim 13, wherein the projection area of the island-shaped protrusion on the bottom portion accounts for 85% to 93% of the total area of the bottom portion.

15. The semiconductor element as claimed in claim 1, wherein the light-emitting diode chip comprises at least one blue light-emitting diode chip.

16. The semiconductor element as claimed in claim 15, wherein the light-emitting diode chip further comprises a green light-emitting diode chip or a red light-emitting diode chip.

17. The semiconductor element as claimed in claim 1, wherein the encapsulating layer comprises a light-transmitting matrix, and a light emitted by the light-emitting diode chip penetrates the light-transmitting matrix.

18. The semiconductor element as claimed in claim 17, wherein the encapsulating layer further comprises a wavelength conversion material dispersed in the light-transmitting matrix.

19. The semiconductor element as claimed in claim 1, wherein the island-shaped protrusion and the bottom portion have the same material.

20. The semiconductor element as claimed in claim 1, wherein the island-shaped protrusion is integrally formed with the bottom portion.
